(19) United States
(12) Patent Application Publication
(10) Pub. No.: US 2005/0174875 A1
(43) Pub. Date: Aug. 11, 2005

(54) Semiconductor storage device

(75) Inventor: Yuukoh Katoh, Tokyo (JP)

Correspondence Address: FOLEY AND LARDNER;SUITE 500, 3000 K STREET NW, WASHINGTON, DC, 20007, US

(73) Assignee: NEC CORPORATION

(21) Appl. No.: 10/513,462

(22) PCT Filed: May 8, 2003
(86) PCT No.: PCT/JP03/05751

(30) Foreign Application Priority Data
May 9, 2002 (JP) 2002-133598

(51) Int. Cl. G11C 8/02

(52) U.S. Cl. 365/232

(57) ABSTRACT

Bit lines (51) and word lines (50) nonparallel to one other are so arranged as to cross, and a magneto-resistance element (52) serving as the storage element is arranged between a bit line and a word line at their intersection. Numeral 106 represents an upper electrode. The magneto-resistance element comprises a free magnetic layer the magnetization direction of which changes with the direction of a current flowing through the bit line at the intersection. The free magnetic layer is located close to the top face of the magneto-resistance element. The distance from the free magnetic layer to the bit line is larger than that from the free magnetic layer to the word line. The width of the word line is smaller than that of the bit line. The bit lines and the word lines are arranged at their respective predetermined repetition pitches. The repetition pitches of the bit lines are larger than those of the word lines.

### TECHNICAL FIELD

The present invention relates to a semiconductor storage device, particularly to a semiconductor storage device in which a tunneling magneto-resistance element (hereinafter referred to as TMR) is used as a memory cell.

### BACKGROUND ART

Hopes have been placed on a semiconductor storage device in which a TMR including a thin insulating barrier held between two ferromagnetic layers and utilizing a tunnel current changing with magnetization states of the ferromagnetic layers as a memory bit is integrated with a transistor, because it is supposed that a highly integrated nonvolatile memory capable of operating at a high speed by driving at a low voltage can be realized.

FIG. 12 shows an example of the TMR reported in 2000 IEEE International Solid-State Circuits Conference DIGEST OF TECHNICAL PAPERS (pp. 128 and 129). In FIG. 12, an antiferromagnetic layer (thickness of 10 nm) 101 formed of FeMn, a pinned layer (thickness of 2.4 nm) 102 formed of CoFe, a tunneling insulating layer 103 formed of Al₂O₃, and a free layer (thickness of 5 nm) 104 formed of NiFe are stacked. The TMR is connected to a conductor wiring (lower and upper electrodes) in such a manner that a voltage can be applied between the antiferromagnetic layer 101 and the free layer 104. The magnetization of the pinned layer 102 is fixed in a certain direction by the antiferromagnetic layer 101. The free layer 104 is formed in such a manner that the layer is easily magnetized in a certain direction, and the magnetization direction can be changed by application of a magnetic field from the outside. In a horizontal direction in a film face, an easily magnetized direction is referred to as an easy axis, and a direction vertical to this easy axis and difficult to magnetize is referred to as a difficult axis. When a voltage is applied between the free layer 104 and the pinned layer 102, a current flows through the tunneling insulating layer 103, but an ohmic value changes with a relation between the direction of the magnetization of the free layer 104 and that of the magnetization of the pinned layer 102. That is, the ohmic value drops in a case where the free layer 104 and the pinned layer 102 have the same magnetization direction, and the ohmic value increases in a case where the directions are opposite to each other.

Next, a conventional example using the TMR as a storage element of a nonvolatile memory will be described with reference to FIG. 13. This example has been reported in the above-described document. In this example, a pair of wirings are disposed above/below TMRs 107 arranged in an array in a horizontal plane. These wirings extend in directions crossing each other at right angles, and intersect with each other. The wirings do not actually intersect, and intersect in the case of projection onto the horizontal plane. An upper wiring (constituting a bit line) 108 which is one wiring is connected to the free layer of the TMR 107 via a conductive layer (not shown). A lower wiring (constituting a write word line) 111 which is the other wiring is positioned under a third wiring 109 positioned under the TMR 107. The antiferromagnetic layer of the TMR 107 is connected to the third wiring 109 via a conductive layer (not shown), and the third wiring 109 is connected to a drain of a transistor 110 formed on a semiconductor substrate disposed below. When currents are passed through two wirings 108, 111, a synthetic magnetic field is generated in the vicinity of an intersection of these wirings, and the direction of the magnetization of the free layer is set in accordance with the direction of the current. Accordingly, the ohmic value of the TMR 107 can be changed, and data is written. To read the data, the transistor 110 connected to the TMR 107 to read is brought into an on-state by a read word line 112, the voltage is applied to the TMR 107 from the upper wiring 108, and the ohmic value of the TMR is evaluated by the current flowing at this time.

In the above-described conventional semiconductor storage device, a magnetoresistance element is disposed in a position closer to the bit line than to the word line. In this case, there is a problem that the memory array cannot be highly integrated. This will be described hereinafter.

With regard to the magnetoresistance element, in general, a shape in a horizontal plane is formed into a shape which is long in one axis direction, for example, a rectangular shape in order that the free layer may have one easy axis constituting the easily magnetized direction as described above (i.e. uniaxial anisotropy may be imparted). In this case, since a substantially long side direction constitutes the easy axis, the bit line is disposed in a direction substantially at right angles to this long side in order to control the direction of the magnetization by the bit line. On the other hand, the word line is disposed substantially at right angles to the bit line. Here, a distance between each wiring and the magnetoresistance element is noted. As shown in FIG. 13, in the conventional example, the TMR 107 is disposed in the vicinity of the bit line (108). On the other hand, the third wiring 109 connected to the transistor, and an interlayer insulating film (not shown) which insulates the third wiring 109 from the write word line (111) are disposed between the TMR 107 and the write word line (111). Therefore, the TMR 107 is disposed apart from the write word line (111) additionally by thicknesses of these third wiring 109 and interlayer insulating film.

Here, integration is considered. As one factor which inhibits the integration, there is a disturbance phenomenon which occurs in performing writing with respect to an adjacent cell. In this phenomenon, data written in the adjacent cell in the magnetized state is collapsed by a magnetic field generated by the wiring in a case where the current is passed through the word line or the bit line to perform the writing with respect to the cell. This phenomenon is influenced by a distance relation between the magnetoresistance element and the wiring to be originally written, and a distance relation between the magnetoresistance element and the adjacent cell. That is, when a pitch between the wirings is smaller, or the distance between the magnetoresistance element and write wiring (word line, bit line) is longer, the write wiring of the magnetoresistance element is not easily distinguished from that of an adjacent element, and therefore a possibility of disturbance increases. In the conventional example, since the distance between the word line and the magnetoresistance element is large, disturbance easily occurs by the word line, and there is a limitation from a viewpoint of suppression of the disturbance in reducing the pitch between the word lines to integrate the device. When reducing the pitch between the bit lines, the possibility of the occurrence of the disturbance decreases, because the bit line is disposed in the vicinity of the magnetoresistance element in the conventional example. However, since the width direction of the bit line is the same as the long-side direction of the magnetoresistance element, the pitch cannot be reduced.

Therefore, there has been a problem that it is difficult to densely arrange both the word line and the bit line, and the integration is difficult.

### DISCLOSURE OF THE INVENTION

An object of the present invention is to provide a semiconductor storage device in which arrangements of a magnetoresistance element and wirings such as a word line and a bit line can be optimized to arrange the magnetoresistance elements at a high density.

In order to attain the above object, according to the present invention, there is provided a semiconductor storage device in which a wiring of a first system and a wiring of a second system nonparallel to each other are so arranged as to intersect, and a magneto-resistance element as a storage element is disposed in a portion corresponding to an intersecting portion between the wiring of the first system and the wiring of the second system, the magneto-resistance element comprising a free magnetic layer whose magnetization direction changes with a direction of a current flowing through the wiring of the first system of the intersecting portion,

wherein a distance from the free magnetic layer to the wiring of the first system is larger than that from the free magnetic layer to the wiring of the second system.

In an aspect of the present invention, the magneto-resistance element is disposed between the wiring of the first system and the wiring of the second system. In an aspect of the present invention, the wiring of the second system is positioned between the magneto-resistance element and the wiring of the first system.

In an aspect of the present invention, a width of the wiring of the second system is smaller than that of the wiring of the first system.

In an aspect of the present invention, the free magnetic layer is positioned in the vicinity of one surface of the magneto-resistance element, and the wiring of the second system is disposed on a side facing the one surface of the magneto-resistance element. In an aspect of the present invention, the free magnetic layer is positioned in the vicinity of one surface of the magneto-resistance element, and the wiring of the second system is disposed on a side facing a surface opposite to the one surface of the magneto-resistance element.

In an aspect of the present invention, the wiring of the first system and the wiring of the second system are arranged at predetermined repetition pitches, and the repetition pitch of the wiring of the first system is lager than that of the wiring of the second system.

In an aspect of the present invention, the magneto-resistance element has a shape longer in one axis direction, especially in a direction of the wiring of the second system rather than a direction of the wiring of the first system.

In an aspect of the present invention, the wiring of the first system is a bit line, and the wiring of the second system is a word line.

In an aspect of the present invention, the wiring of the first system is a write bit line, the wiring of the second system is a word line, and a read bit line having the same direction as that of the wiring of the first system is disposed separately from the wiring of the first system and the wiring of the second system. In an aspect of the present invention, the semiconductor storage device further comprises: a bit line control circuit which executes a control in such a manner as to supply a current for writing to both the write bit line and the read bit line. In an aspect of the present invention, the read bit line is disposed on the same side as that of the write bit line with respect to the magneto-resistance element. In an aspect of the present invention, the read bit line is disposed on a side opposite to that of the write bit line with respect to the magneto-resistance element.

In an aspect of the present invention, the magneto-resistance element is constituted of the free magnetic layer, a tunneling insulating layer, a pinned magnetic layer, and an antiferromagnetic layer stacked in this order.

In an aspect of the present invention, the wiring of the first system is constituted of a plurality of layers constituting the wiring of the first system, and the distance from the free magnetic layer to the wiring of the first system is a distance from the free layer to a layer in which a current flows mainly in the layers corresponding the wiring of the first system. In an aspect of the present invention, the wiring of the second system is constituted of a plurality of layers constituting the wiring of the second system, and the distance from the free magnetic layer to the wiring of the second system is a distance from the free layer to a layer in which a current flows mainly in the layers corresponding the wiring of the second system.

In an aspect of the present invention, the magneto-resistance element is connected in series to a resistance element having nonlinear characteristics.

In the present invention described above, in the wirings of the first and second systems, the wiring having a larger distance from the free magnetic layer of the magnetoresistance element is constituted as the bit line or the write bit line which is a wiring having a comparatively large width and arrangement pitch, and the wiring having a smaller distance from the free magnetic layer of the magnetoresistance element is constituted as the word line which is a wiring having a comparatively small width and arrangement pitch, so that disturbance is suppressed, and the arrangement pitch of the word line can be reduced than before. Accordingly, storage cells can be arranged at a high density, and miniaturization and capacity enlargement of the semiconductor storage device are possible by high integration.

### BRIEF DESCRIPTION OF THE DRAWINGS

FIG. 1 is a partial plan view of a memory cell array section of a semiconductor storage device according to a first embodiment of the present invention;

FIG. 2A is a sectional view along line X-X′ of FIG. 1;

FIG. 2B is a sectional view along line Y-Y′ of FIG. 1;

FIG. 2C is a partially sectional view of FIG. 1;

FIG. 3 is a schematic circuit diagram of the first embodiment of the present invention;

FIG. 4 is a sectional view of a TMR according to the first embodiment of the present invention;

FIG. 5 is a partial plan view of the memory cell array section of the semiconductor storage device according to a second embodiment of the present invention;

FIG. 6A is a sectional view along line X-X′ of FIG. 5;

FIG. 6B is a sectional view along line Y-Y′ of FIG. 5;

FIG. 6C is a partially sectional view of FIG. 5;

FIG. 7 is a partial plan view of the memory cell array section of the semiconductor storage device according to a third embodiment of the present invention;

FIG. 8A is a sectional view along line X-X′ of FIG. 7;

FIG. 8B is a sectional view along line Y-Y′ of FIG. 7;

FIG. 8C is a partially sectional view of FIG. 7;

FIG. 9 is a schematic circuit diagram of the third embodiment of the present invention;

FIG. 10 is a partial plan view of the memory cell array section of the semiconductor storage device according to a fourth embodiment of the present invention;

FIG. 11A is a sectional view along line X-X′ of FIG. 10;

FIG. 11B is a sectional view along line Y-Y′ of FIG. 10;

FIG. 11C is a partially sectional view of FIG. 10;

FIG. 12 is a sectional view of a TMR for use in a conventional semiconductor storage device; and

FIG. 13 is a schematically perspective view of the conventional semiconductor storage device.

### BEST MODE FOR CARRYING OUT THE INVENTION

Next, embodiments of the present invention will be described in detail with reference to the drawings.

### First Embodiment

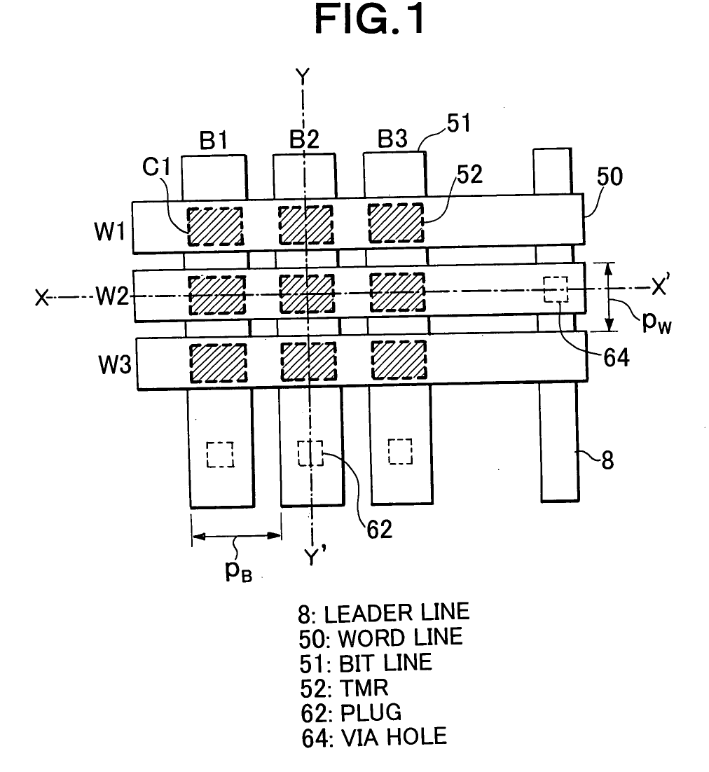

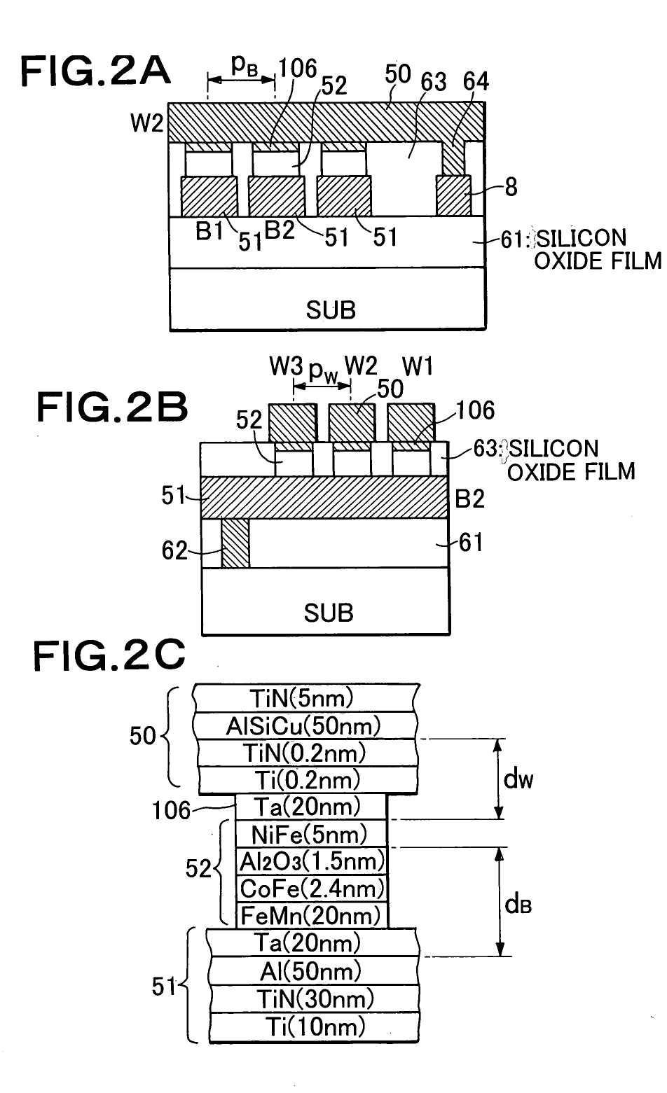

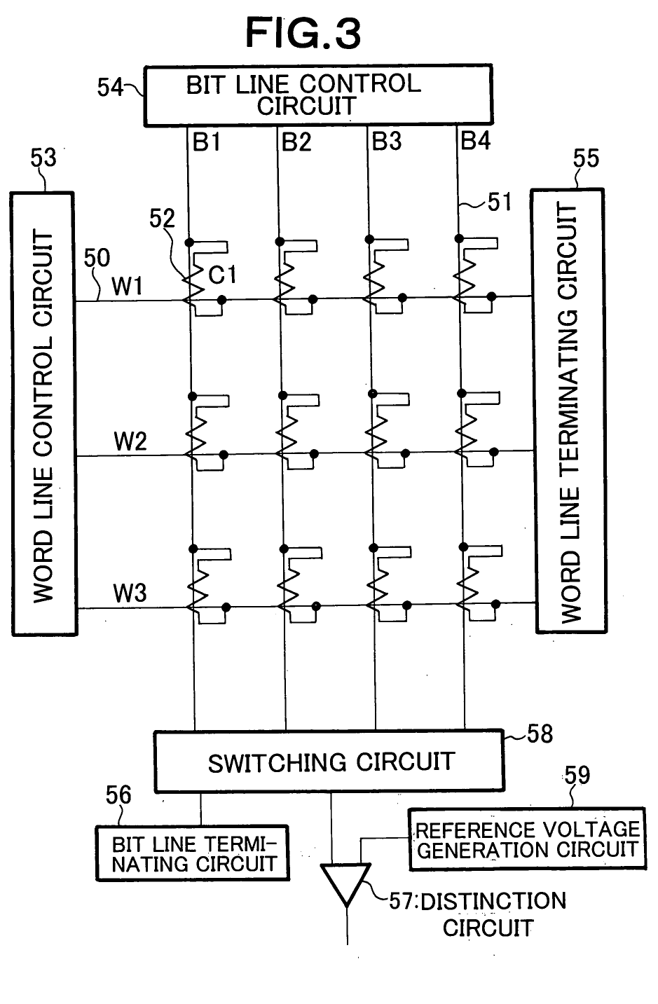

FIG. 1 is a partial plan view of a memory cell array section of a semiconductor storage device according to a first embodiment of the present invention, FIG. 2A is a sectional view along line X-X′ of FIG. 1, FIG. 2B is a sectional view along line Y-Y′ of FIG. 1, and FIG. 2C is a partially sectional view of FIG. 1. FIG. 3 is a schematic circuit diagram of the first embodiment.

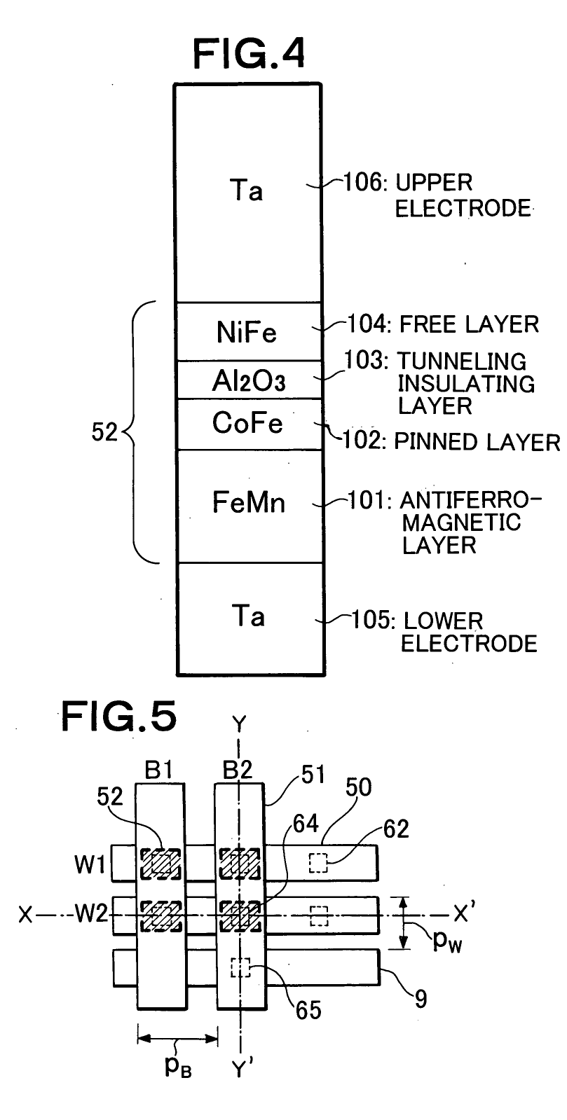

The semiconductor storage device of the present embodiment has word lines (W1, W2, W3) 50, bit lines (B1, B2, B3, B4) 51, TMRs (C1) 52, a word line control circuit 53, a bit line control circuit 54, a word line terminating circuit 55, a bit line terminating circuit 56, a distinction circuit 57, a switching circuit 58, and a reference voltage generation circuit 59. In FIG. 1, the bit line B4 is omitted. As shown in FIG. 1, the TMRs 52 are formed in intersecting portions between the word lines 50 and the bit lines 51 as viewed in the plan view. FIG. 4 shows a sectional view of portions of the TMR 52. The TMR 52 is disposed between a lower electrode 105 and an upper electrode 106, and an antiferromagnetic layer 101, a pinned layer 102 (ferromagnetic layer), a tunneling insulating layer 103, and free layer (ferromagnetic layer) 104 are stacked to constitute the TMR. The free layer 104 contacts the upper electrode 106, and the antiferromagnetic layer 101 contacts the lower electrode 105. The upper electrode 106 contacts the word line 50, and may constitute a part of the word line. The lower electrode 105 is connected to the bit line 51, and may constitute a part of the bit line. In this manner, the upper and lower electrodes for the TMR 52, especially the lower electrode may constitute a part of the wiring connected to the electrodes (this also applies to the following embodiments).

As shown in FIGS. 2A, 2B, 2C, and 3, one electrode (upper electrode) 106 for the TMR 52 is connected to the word line 50, and the other electrode (lower electrode) is connected to the bit line 51. Especially, in the present embodiment, the lower electrode 105 constitutes a part of the bit line 51. As shown in FIG. 3, one end of the word line 50 is connected to the word line control circuit 53, and the other end thereof is connected to the word line terminating circuit 55. One end of the bit line 51 is connected to the bit line control circuit 54, and the other end thereof is connected to both the bit line terminating circuit 56 and one input terminal of the distinction circuit 57 via the switching circuit 58. Another input terminal of the distinction circuit 57 is connected to an output terminal of the reference voltage generation circuit 59.

The word line control circuit 53 has a function of selecting a desired word line to flow a write current therethrough, and a function of applying a read voltage. The bit line control circuit 54 has a function of selecting a desired bit line to flow a write current therethrough in accordance with data, and a function of detaching the bit line. The switching circuit 58 has a function of switching whether to connect the bit line terminating circuit 56 or the distinction circuit 57 to the bit line 51. The distinction circuit 57 has a function of comparing a potential of the connected bit line with a reference potential input from the reference voltage generation circuit 59 to output a potential corresponding to “1”, “0” of data in accordance with the result of the comparison. The distinction circuit 57 may compare a current flowing through the bit line with a reference current.

Next, a method of manufacturing the semiconductor storage device of the present embodiment will be described. As to the semiconductor storage device, after forming elements (not shown) such as transistors or a lower-layer wiring (not shown) on a silicon substrate SUB, a silicon oxide film 61 is formed by a plasma CVD process, and flattened by chemical mechanical polishing (CMP) process. The silicon oxide film 61 of a portion to be electrically connected to the lower-layer wiring is partially removed using a photolithography technique and a dry etching technique, tungsten is buried by the CVD process, thereafter the CMP process is performed again to flatten the film, and a plug 62 is formed.

Thereafter, a Ti layer (thickness of 10 nm), a TiN layer (thickness of 30 nm), an Al layer (thickness of 50 nm), and a Ta layer (thickness of 20 nm) for forming the bit line 51 and a leader line 8 are continuously formed by a sputtering process.

Subsequently, after continuously forming an FeMn layer (thickness of 20 nm), a CoFe layer (thickness of 2.4 nm), and an Al layer (thickness of 1.5 nm) for forming the TMR 52 by the sputtering process, the layers are stored in an oxygen atmosphere, and the Al layer is oxidized into an Al₂O₃ layer. Thereafter, an NiFe layer (thickness of 5 nm), and a Ta layer (thickness of 40 nm) are continuously formed by the sputtering process.

Next, resist is applied, baked, exposed, and developed to form a resist film having a shape of the TMR to be formed. Thereafter, the Ta layer, NiFe layer, Al₂O₃ layer, CoFe layer, and FeMn layer are patterned by ion milling to form the TMR 52 and upper electrode 106.

After removing the resist film by an organic solvent, the resist film having a pattern of the bit line 51 to be formed is formed by the above-described photolithography technique, and the Ta layer, Al layer, TiN layer, and Ti layer are processed by the dry etching technique to form the bit lines 51 and the leader line 8.

After removing the resist film by the organic solvent, a silicon oxide film 63 is formed into a thickness of 300 nm over the whole surface by the CVD process. Moreover, the film is flattened by the CMP process, so that the Ta layer on the TMR 52 is left in a thickness of about 20 nm. After removing the silicon oxide film 63 of the portion connected to the leader line 8 in the same layer as that of the bit line 51 by the photolithography technique and dry etching technique to form a via hole 64, a Ti layer (thickness of 0.2 nm), a TiN layer (thickness of 0.2 nm), an AlSiCu layer (thickness of 50 nm), and a TiN layer (thickness of 5 nm) are continuously formed by the sputtering process, and patterned by the photolithography and dry etching techniques to form the word lines 50. The word line (W2) 50 is electrically connected to the leader line 8 formed on the same plane as that of the bit line 51 via the via hole 64.

In a structure of the TMR 52 of the present embodiment, the NiFe layer is a free layer, and data is written and stored therein as a direction of magnetization. A region of the word line 50 in which a current flows mainly is a portion of the AlSiCu layer from conductivity, thickness and the like of materials of the respective layers. Similarly, a region of the bit line 51 in which the current flows mainly is a portion of the Al layer from conductivity, thickness and the like of the materials of the respective layers.

When a layer constituted of a material having a nonlinear resistance, such as amorphous silicon, or a stacked structure including the layer is formed before/after forming the layer constituting the TMR, nonlinear characteristics can be imparted to the TMR (this also applies to the following embodiments).

Next, a method of using the semiconductor storage device will be described. This semiconductor storage device constitutes a nonvolatile memory in which the TMR is used as a storage element. As shown in FIG. 1, each TMR 52 has a rectangular shape having a long side in a bit line width direction in a plan view, and a magnetized state changes with a current magnetic field of the bit line 51 because of this shape anisotropy.

First, writing of data will be described. To write the data into the cell C1 (TMR) formed on the intersecting portion between the bit line B1 and the word line W1, first the bit line 51 is connected to the bit line terminating circuit 56 by the switching circuit 58. When the current is passed through the word line W1 by the word line control circuit 53, and the current having a direction corresponding to the data is passed through the bit line B1 by the bit line control circuit 54, a synthetic magnetic field is applied to the TMR 52 of the cell C1 in the intersection, and the free layer is magnetized in accordance with the direction of the current of the bit line 51. Even after stopping the current, the direction of the magnetization of the free layer is held by the shape anisotropy of the free layer.

Next, reading of the data will be described. The bit line B1 is disconnected from the bit line control circuit 54, and the bit line B1 is connected to the distinction circuit 57 by the switching circuit 58. A voltage of about 0.5 V is applied to the word line W1. The other wirings are grounded. As to the TMR 52 disposed in the intersection between the word line W1 and the bit line B1, since the ohmic value thereof changes in accordance with the direction of the magnetization of the free layer, a potential rise speed of the bit line B1 differs with the direction of the magnetization of the free layer. After elapse of 100 ns, the distinction circuit 57 compares the voltage with a reference voltage set at a circuit design time and output from the reference voltage generation circuit 59 to thereby distinguish the direction of the magnetization, so that the written data can be read. The reference voltage is determined based on the ohmic value of the memory cell measured after manufacturing the memory cell. The determined value may be stored in the reference voltage generation circuit 59. As a method of distinguishing the direction of the magnetization, there are: a method in which the above-described read bit line potential is stored beforehand, and known data is written into the read cell, and compared with a bit line voltage at a time when the data is read again; a method in which complementary data is written in another cell, and compared with an output bit line potential of the cell to distinguish the data on the basis of the comparison result, and the like.

In the present embodiment, an arrangement pitch p_{W} of the word line 50 is 0.6 μm, a word line width is 0.3 μm, an arrangement pitch p_{B} of the bit lines 51 is 0.8 μm, a bit line width is 0.5 μm, and a size of the TMR 52 is 0.25 μm×0.45 μm. A distance d_{W} from a region (AlSiCu layer) of the word line 50 in which the current flows mainly to the free layer of the TMR 52 is about 20 nm. A distance d_{B} from a region (Al layer) of the bit line 51 in which the current flows mainly to the free layer of the TMR 52 is about 44 nm. The bit line 51 has a large distance from the free layer as compared with the word line 50 in this manner, but has a larger pitch, and therefore a possibility that disturbance is caused is low. Since the distance from the free layer is small in the word line 50, a possibility that the disturbance is caused is low, and the pitch can be reduced.

### Second Embodiment

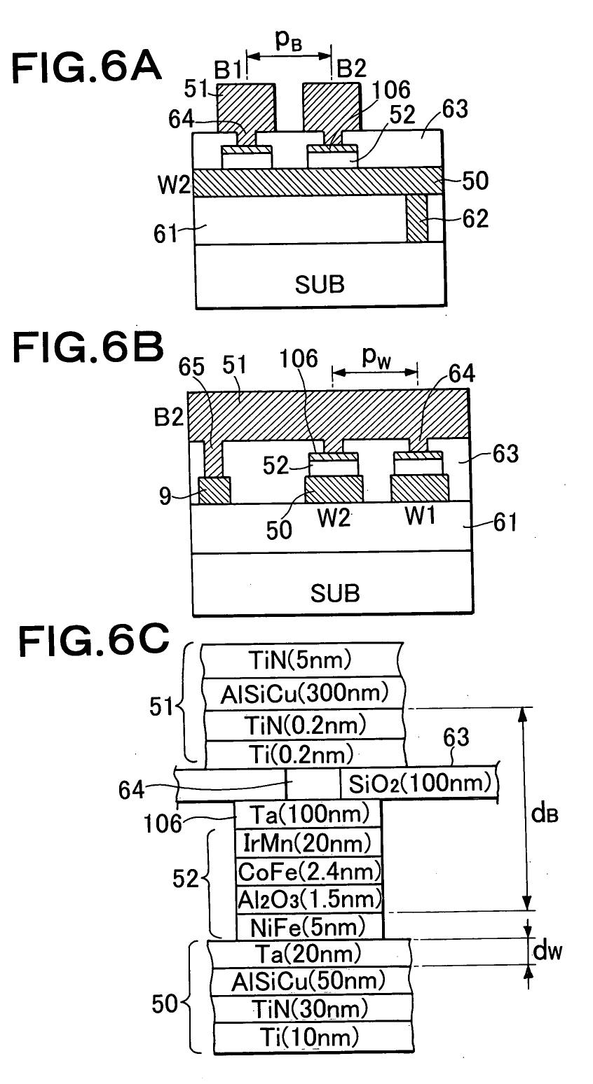

Next, a second embodiment will be described with reference to FIGS. 5, 6A, 6B, and 6C.

FIG. 5 is a partial plan view of a cell array section of the semiconductor storage device according to a second embodiment of the present invention, FIG. 6A is a sectional view along line X-X′ of FIG. 5, FIG. 6B is a sectional view along line Y-Y′ of FIG. 5, and FIG. 6C is a partially sectional view of FIG. 5. A circuit constitution of this semiconductor storage device is the same as that of the first embodiment shown in FIG. 3.

Next, a method of manufacturing the semiconductor storage device of the present embodiment will be described. As to the semiconductor storage device, after forming elements (not shown) such as transistors or a lower-layer wiring (not shown) on a silicon substrate SUB, a silicon oxide film 61 is formed by a plasma CVD process, and flattened by CMP process. The silicon oxide film 61 of a portion to be electrically connected to the lower-layer wiring is partially removed using a photolithography technique and a dry etching technique to form a via hole, tungsten is buried by the CVD process, thereafter the CMP process is performed again to flatten the film, and a plug 62 is formed.

Thereafter, a Ti layer (thickness of 10 nm), a TiN layer (thickness of 30 nm), an AlSiCu layer (thickness of 50 nm), and a Ta layer (thickness of 20 nm) for forming a word line 50 and a leader line 9 are continuously formed by a sputtering process.

Subsequently, after continuously forming an NiFe layer (thickness of 5 nm), and an Al layer (thickness of 1.5 nm) for forming a TMR 52 by the sputtering process, the Al layer is oxidized into an Al₂O₃ layer by plasma oxidation. Thereafter, a CoFe layer (thickness of 2.4 nm), an IrMn layer (thickness of 20 nm), and a Ta layer (thickness of 100 nm) are continuously formed by the sputtering process.

The Ta layer, IrMn layer, CoFe layer, Al₂O₃ layer, and NiFe layer are patterned by the photolithography technique and an ion milling technique to form the TMR 52 and upper electrode 106. After removing the resist film by an organic solvent, the Ta layer, AlSiCu layer, TiN layer, and Ti layer are processed by the photolithography and dry etching techniques to form the word lines 50 and leader line 9.

After removing the resist film by the organic solvent, a silicon oxide film 63 is formed into a thickness of 400 nm over the whole surface by the sputtering process. The film is flattened by the CMP process until the silicon oxide film 63 having a thickness of about 100 nm remains on the TMR 52, a via hole 64 is formed on the TMR 52 using the photolithography technique and dry etching technique, and further a via hole 65 is formed in a portion to be connected to the leader line 9 of the same layer as that of the word line 50.

A Ti layer (thickness of 0.2 nm), a TiN layer (thickness of 0.2 nm), an AlSiCu layer (thickness of 300 nm), and a TiN layer (thickness of 5 nm) for forming the bit line 51 are continuously formed by the sputtering process, and patterned by the photolithography and dry etching techniques to form bit lines (B1, B2) 51. The bit line (B2) 51 is connected to the TMR 52 via the via hole 64, and further electrically connected to the leader line 9 formed on the same plane as that of the word line 50 via the via hole 65.

As shown in FIGS. 6A, 6B, and 6C, one electrode (upper electrode) 106 for the TMR 52 is connected to the bit line 51, and the other electrode (lower electrode) is connected to the word line 50. Especially in the present embodiment, the lower electrode constitutes a part of the bit line 51.

In a structure of the TMR 52 of the present embodiment, the NiFe layer is a free layer, and data is written and stored therein as a direction of magnetization. A region of the word line 50 in which a current flows mainly is a portion of the AlSiCu layer from conductivity, thickness and the like of materials of the respective layers. Similarly, a region of the bit line 51 in which the current flows mainly is a portion of the AlSiCu layer from the conductivity, thickness and the like of the materials of the respective layers.

A method of using this semiconductor storage device is similar to that of the first embodiment.

In the present embodiment, an arrangement pitch p_{W} of the word line 50 is 1.2 μm, a word line width is 0.6 μm, an arrangement pitch p_{B} of the bit line 51 is 1.6 μm, a bit line width is 0.8 μm, and a size of the TMR 52 is 0.5 μm×0.7 μm. A distance d_{W} from a region (AlSiCu layer) of the word line 50 in which the current flows mainly to the free layer of the TMR 52 is about 20 nm. A distance d_{B} between the free layer of the TMR 52 and a region (AlSiCu layer) of the bit line 51 in which the current flows mainly is about 224 nm. The bit line 51 has a large distance from the free layer as compared with the word line 50 in this manner, but has a larger pitch, and therefore a possibility that disturbance is caused is low. Since the distance from the free layer is small in the word line 50, a possibility that the disturbance is caused is low, and the pitch can be reduced.

### Third Embodiment

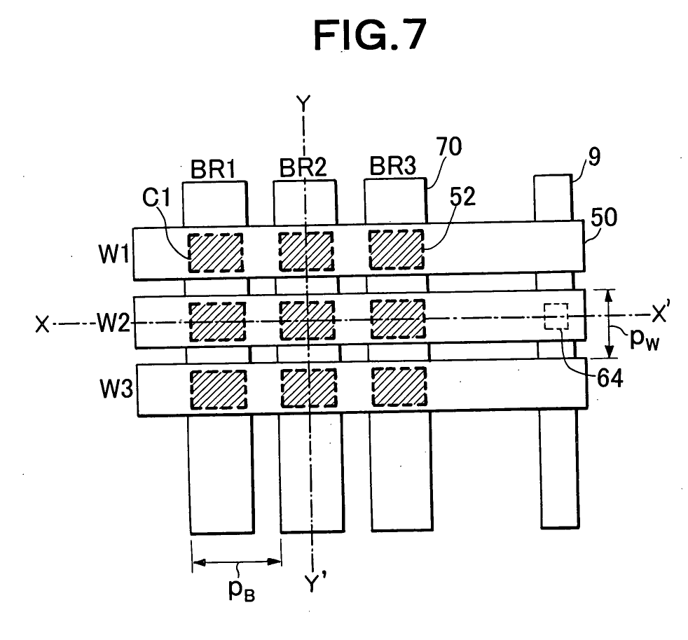

Next, a third embodiment will be described with reference to FIGS. 7, 8A, 8B, 8C, and 9.

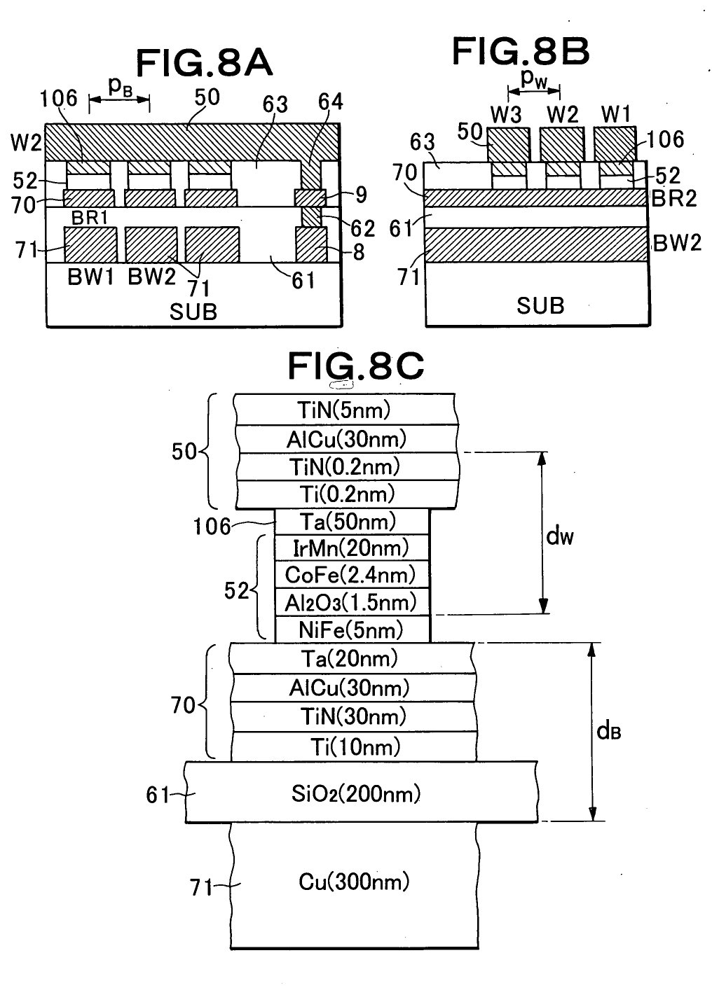

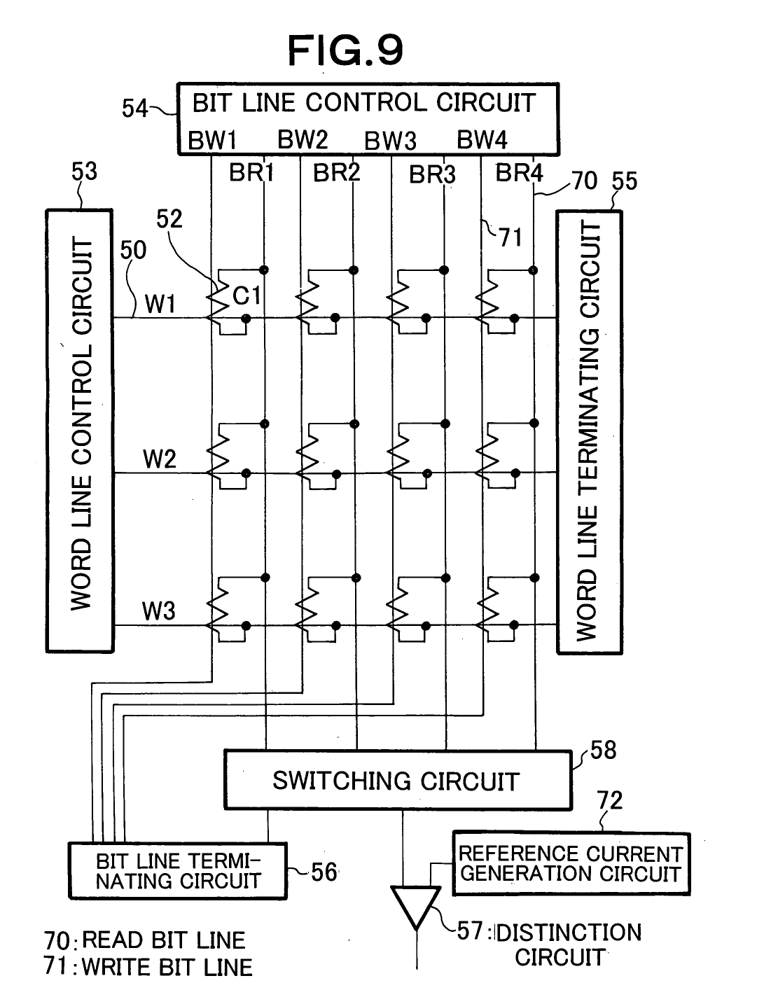

FIG. 7 is a partial plan view of a memory cell section of the semiconductor storage device according to a third embodiment of the present invention, FIG. 8A is a sectional view along line X-X′ of FIG. 7, FIG. 8B is a sectional view along line Y-Y′ of FIG. 7, and FIG. 8C is a partially sectional view of FIG. 7. FIG. 9 is a schematic circuit diagram of the third embodiment.

This semiconductor storage device has word lines (W1, W2, W3) 50, read bit lines (BR1, BR2, BR3, BR4) 70, write bit lines (BW1, BW2, BW3, BW4) 71, TMRs 52, a word line control circuit 53, a bit line control circuit 54, a word line terminating circuit 55, a bit line terminating circuit 56, a distinction circuit 57, a switching circuit 58, and a reference current generation circuit 72. In FIG. 7, the read bit line BR4 and the write bit line BW4 are omitted. As shown in FIG. 7, the TMRs 52 are formed in intersecting portions between the word lines 50 and the read bit lines 70 as viewed in the plan view. The write bit line 71 is formed in a corresponding position right under the read bit line 70 via an insulating film 61. One electrode for the TMR 52 is connected to the word line 50, and the other electrode is connected to the read bit line 70. One end of the word line 50 is connected to the word line control circuit 53, and the other end is connected to the word line terminating circuit 55. One end of the write bit line 71 is connected to the bit line control circuit 54, and the other end is connected to the bit line terminating circuit 56. One end of the read bit line 70 is connected to the bit line control circuit 54, and the other end is connected to both the bit line terminating circuit 56 and one input terminal of the distinction circuit 57 via the switching circuit 58. Another input terminal of the distinction circuit 57 is connected to an output terminal of the reference current generation circuit 72.

The word line control circuit 53 has a function of selecting a desired word line 50 to flow a write current therethrough, and a function of grounding the desired word line. The bit line control circuit 54 has a function of selecting a desired write bit line 71 to flow a write current therethrough in accordance with data, a function of selecting a desired read bit line 70 to flow a write current therethrough in accordance with the data, and a function of detaching the desired read bit line. The switching circuit 58 has a function of switching whether to connect the bit line terminating circuit 56 or the distinction circuit 57 to the read bit line 70. The distinction circuit 57 has a function of comparing a current flowing in the connected read bit line with a reference current input from the reference current generation circuit 72 to output a potential corresponding to “1”, “0” of data in accordance with the result of the comparison.

Next, a method of manufacturing the semiconductor storage device will be described. As to the semiconductor storage device, after forming elements (not shown) such as transistors, and a lower-layer wiring including the write bit line 71 constituted of a Cu layer (thickness of 30 nm) and the leader line 8 on a silicon substrate SUB, the silicon oxide film 61 is formed by a plasma CVD process, and flattened by CMP process. The silicon oxide film 61 of a portion to be electrically connected to the lower-layer wiring is partially removed using a photolithography technique and a dry etching technique to form a via hole, tungsten is buried by the CVD process, thereafter the CMP process is performed again to flatten the film in such a manner that the silicon oxide film remains in a thickness of 200 nm on the write bit line 71, and a plug 62 is formed.

Thereafter, a Ti layer (thickness of 10 nm), a TiN layer (thickness of 30 nm), an AlCu layer (thickness of 30 nm), and a Ta layer (thickness of 20 nm) for forming the read bit line 70 are continuously formed by a sputtering process.

Subsequently, after continuously forming an NiFe layer (thickness of 5 nm), and an Al layer (thickness of 1.5 nm) for forming the TMR 52 by the sputtering process, the layers are stored in an oxygen atmosphere, and the Al layer is oxidized into an Al₂O₃ layer. Thereafter, a CoFe layer (thickness of 2.4 nm), an IrMn layer (thickness of 20 nm), and a Ta layer (thickness of 100 nm) are continuously formed by the sputtering process.

The Ta layer, IrMn layer, CoFe layer, Al₂O₃ layer, and NiFe layer are processed by the photolithography technique and an ion milling technique to form the TMR 52 and an upper electrode 106. After removing the resist film by an organic solvent, the Ta layer, AlCu layer, TiN layer, and Ti layer are processed into desired shapes by the photolithography and dry etching techniques to form the read bit line 70 and leader line 9.

After removing the resist film by the organic solvent, a silicon oxide film 63 is formed into a thickness of 300 nm over the whole surface by the sputtering process, and flattened by the CMP process, so that the Ta layer on the TMR 52 remains in a thickness of about 50 nm. After removing the silicon oxide film 63 of a portion to be connected to the leader line 9 of the same layer as that of the read bit line 70 by the photolithography and dry etching techniques to form a via hole 64, a Ti layer (thickness of 0.2 nm), a TiN layer (thickness of 0.2 nm), an AlCu layer (thickness of 30 nm), and a TiN layer (thickness of 5 nm) are continuously formed by the sputtering process to form the word lines 50 by the photolithography and dry etching techniques. The word line (W2) 50 is electrically connected to the leader line 9 formed on the same plane as that of the read bit line 70 via the via hole 64. The leader line 9 is electrically connected to the leader line 8 formed on the same plane as that of the write bit line 71 via the plug 62.

In a structure of the TMR 52 of the present embodiment, the NiFe layer is a free layer, and data is written and stored therein as a direction of magnetization. A region of the word line 50 in which a current flows mainly is a portion of the AlCu layer from conductivity, thickness and the like of materials of the respective layers. Similarly, a region of the read bit line 70 in which the current flows mainly is a portion of the AlCu layer from the conductivity, thickness and the like of the materials of the respective layers.

A vertical relation of the read bit line 70 and write bit line 71 and the word line 50 with respect to the TMR 52 may be reversed. That is, the word line 50, TMR 52, read bit line 70, and write bit line 71 may be disposed on the substrate in this order. The vertical relation between the read bit line 70 and the write bit line 71 may be reversed. The order of the layer constitution of the TMR 52 may be reversed. Additionally, a size relation between the distance from the free layer of the TMR 52 to the region of the word line 50 in which the current flows mainly, and the distance from the free layer of the TMR 52 to the region of the write bit line 71 in which the current flows mainly is maintained as described above.

Next, a method of using this semiconductor storage device will be described. This semiconductor storage device constitutes a nonvolatile memory in which the TMR is used as a storage element (cell). As shown in FIG. 7, each TMR 52 has a rectangular shape having a long side in a write bit line width direction in a plan view, and a magnetized state changes with a current magnetic field of the write bit line 71 because of this shape anisotropy.

Writing of data will be described. To write the data into the TMR cell C1 formed on the intersecting portion between the word line W1 and the write bit line BW1, first the read bit line 70 is connected to the bit line terminating circuit 56 by the switching circuit 58. When the current is passed through the word line W1 by the word line control circuit 53, and the current having a direction corresponding to the data is passed through the write bit line BW1 and the read bit line BR1 by the bit line control circuit 54, a synthetic magnetic field is applied to the TMR 52 in the intersection, and the free layer is magnetized in accordance with the direction of the current of the bit line. Even after stopping the current, the direction of the magnetization of the free layer is held by the shape anisotropy of the free layer. It is to be noted that the data may be written only by the current of the write bit line 71 without flowing any current through the read bit line 70.

Next, reading of the data will be described. The read bit line BR1 is disconnected by the bit line control circuit 54, and is connected to the distinction circuit 57 by the switching circuit 58. Moreover, the word line W1 is grounded. As to the other word lines, a potential is set to be equal to that of a constant voltage source which supplies the current to the TMR cell C1 of the distinction circuit 57. As to the TMR 52 in the intersection between the word line W1 and the read bit line BR1, since an ohmic value thereof changes in accordance with the direction of the magnetization, an amount of a current flowing into the read bit line BR1 differs. The current is compared with a reference current value of the reference current generation circuit 72 by the distinction circuit 57 to thereby distinguish the direction of the magnetization, so that the written data can be read.

In the present embodiment, an arrangement pitch p_{W} of the word line 50 is 0.6 μm, a word line width is 0.3 μm, arrangement pitches p_{B} of the write bit line 71 and the read bit line 70 are 0.8 μm, a write bit line width and a read bit line width are 0.5 μm, and a size of the TMR is 0.25 μm×0.45 μm. A distance d_{W} from a region (AlCu layer) of the word line 50 in which the current flows mainly to the free layer of the TMR 52 is about 74 nm. A distance d_{B} from the free layer of the TMR 52 to the write bit line 71 is about 290 nm. The write bit line 71 is distant from the free layer as compared with the word line 50 in this manner, but has a larger pitch, and therefore a possibility of occurrence of disturbance is low. Since the distance between the word line 50 and the free layer is small, the possibility of the occurrence of the disturbance is low, and the pitch can be reduced.

Moreover, in the structure of this embodiment, there are advantages that a material and structure in which the current is easily flown can be set to the write bit line 71, and a structure and material advantageous in forming the good-quality TMR 52 can be set to the read bit line 70 in a resistance range capable of reading the data.

### Fourth Embodiment

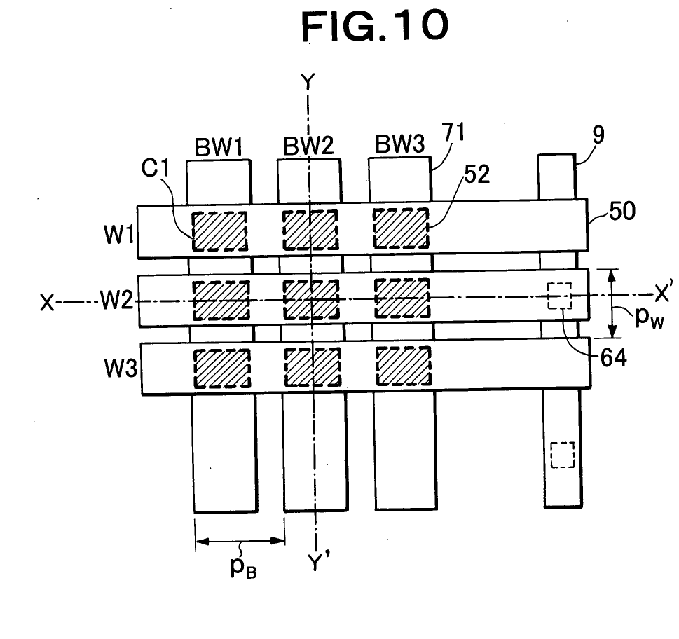

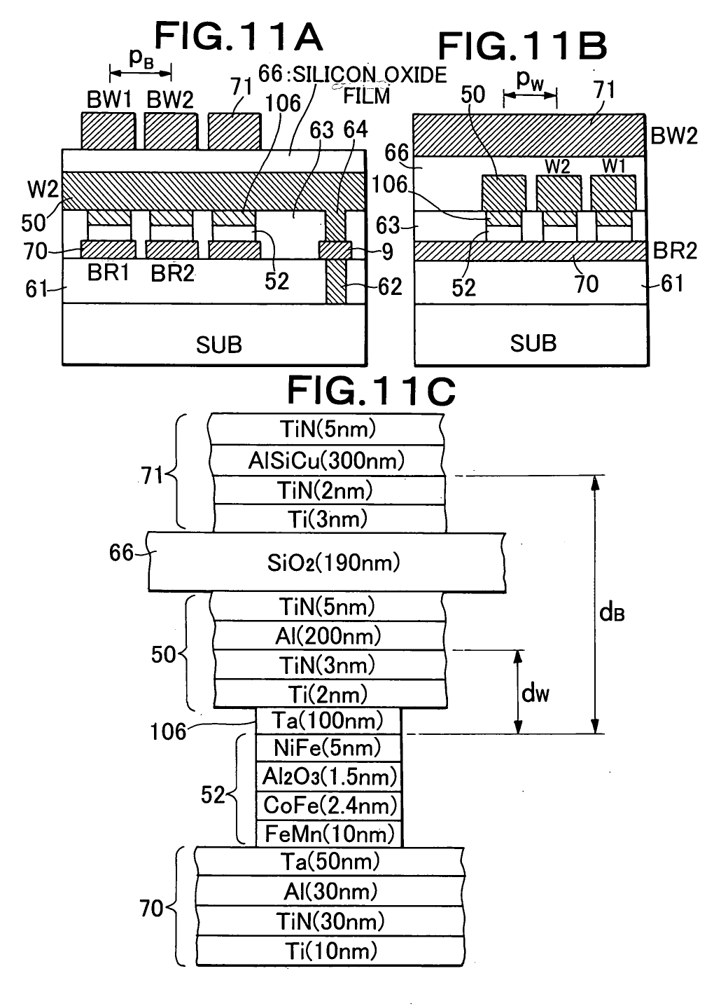

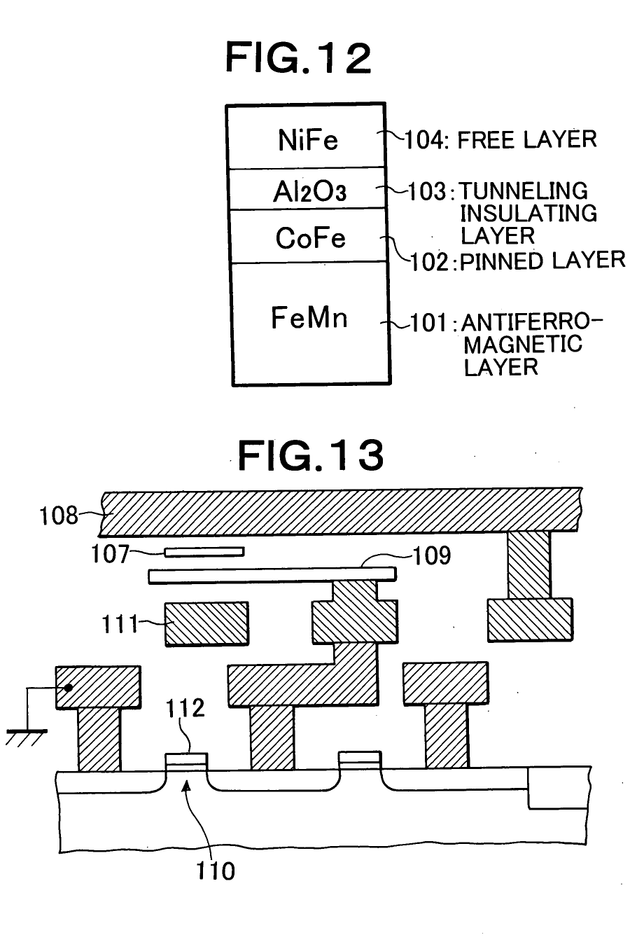

Next, a fourth embodiment will be described with reference to FIGS. 10, 11A, 11B, and 11C.

FIG. 10 is a partial plan view of a cell array section of a semiconductor storage device according to a fourth embodiment of the present invention, FIG. 11A is a sectional view along line X-X′ of FIG. 10, FIG. 11B is a sectional view along line Y-Y′ of FIG. 10, and FIG. 11C is a partially sectional view of FIG. 10. A circuit constitution of the semiconductor storage device is similar to that of the third embodiment shown in FIG. 9.

A method of manufacturing the semiconductor storage device of the present embodiment will be described. As to the semiconductor storage device, after forming elements (not shown) such as transistors or a lower-layer wiring (not shown) on a silicon substrate SUB, a silicon oxide film 61 is formed by a plasma CVD process, and flattened by CMP process. The silicon oxide film 61 of a portion to be electrically connected to the lower-layer wiring is partially removed using a photolithography technique and a dry etching technique, tungsten is buried by the CVD process, thereafter the CMP process is performed again to flatten the film so that a 200 nm thick silicon oxide film is left, and a plug 62 is formed.

Thereafter, a Ti layer (thickness of 10 nm), a TiN layer (thickness of 30 nm), an Al layer (thickness of 30 nm), and a Ta layer (50 nm) for forming the read bit line 70 are continuously formed by a sputtering process. Next, after continuously forming an FeMn layer (thickness of 10 nm), a CoFe layer (thickness of 2.4 nm), and an Al layer (thickness of 1.5 nm) for forming the TMR 52 on the whole surface by the sputtering process, the layers are stored in an oxygen atmosphere, and the Al layer is oxidized to form an Al₂O₃ layer. Thereafter, an NiFe layer (thickness of 5 nm), and a Ta layer (thickness of 100 nm) are continuously formed by the sputtering process.

The Ta layer, NiFe layer, Al₂O₃ layer, CoFe layer, and FeMn layer are processed by the photolithography technique and an ion milling technique to form the TMR 52 and upper electrode 106. After removing the resist film by an organic solvent, the Ta layer, Al layer, TiN layer, and Ti layer are processed by the photolithography and dry etching techniques to form the read bit line 70 and the leader line 9.

After removing the resist film by the organic solvent, a silicon oxide film 63 is formed into a thickness of 300 nm over the whole surface by the sputtering process, the surface of the film is flattened by CMP process, and the Ta layer on the TMR 52 is exposed. Next, after removing the silicon oxide film 63 of the portion connected to the leader line 9 in the same layer as that of the read bit line 70 by the photolithography and dry etching techniques to form a via hole 64, a Ti layer (thickness of 2 nm), a TiN layer (thickness of 3 nm), an Al layer (thickness of 200 nm), and a TiN layer (thickness of 5 nm) are continuously formed by the sputtering process, and the word line 50 is formed by the photolithography and dry etching techniques. The word line (W2) 50 is electrically connected to the leader line 9 formed on the same plane as that of the read bit line 70 via the via hole 64. The leader line 9 is electrically connected to the lower-layer wiring via the plug 62.

Furthermore, after a silicon oxide film 66 is formed, and flattened in such a manner that the thickness of the film on the word line 50 is 190 nm, a Ti layer (thickness of 3 nm), a TiN layer (thickness of 2 nm), an AlSiCu layer (thickness of 300 nm), and a TiN layer (thickness of 5 nm) are continuously formed by the sputtering process, and patterned by the photolithography and dry etching techniques to form the write bit line 71.

In a structure of the TMR 52 of the present embodiment, the NiFe layer is a free layer, and data is written and stored therein as a direction of magnetization. A region of the word line 50 in which a current flows mainly is a portion of the Al layer from conductivity, thickness and the like of materials of the respective layers. Similarly, a region of the write bit line 71 in which the current flows mainly is a portion of the AlSiCu layer from the conductivity, thickness and the like of the materials of the respective layers. Similarly, a region of the read bit line 70 in which the current flows mainly is a portion of the Al layer from the conductivity, thickness and the like of the materials of the respective layers.

A vertical relation of the write bit line 71 and word line 50 and the read bit line 70 with respect to the TMR 52 may be reversed. That is, the write bit line 71, word line 50, TMR 52, and read bit line 70 may be disposed on the substrate in this order. The order of the layer constitution of the TMR 52 may be reversed.

A method of using this semiconductor storage device is similar to that of the third embodiment, but, in order to apply a write magnetic field of the same direction to the TMR 52 at a writing time, the current passed through the write bit line 71 is controlled in such a manner as to have a direction opposite to that of the current passed through the read bit line 70 by the bit line control circuit 54.

In the present embodiment, an arrangement pitch p_{W} of the word line 50 is 0.6 μm, a word line width is 0.3 μm, arrangement pitches p_{B} of the write bit line 71 and read bit line 70 are 0.8 μm, a write bit line width and read bit line width are 0.5 μm, and a size of the TMR is 0.25 μm×0.45 μm. A distance d_{W} from a region (Al layer) of the word line 50 in which the current flows mainly to the free layer of the TMR 52 is about 105 nm. A distance d_{B} from the free layer of the TMR 52 to a region (AlSiCu layer) of the write bit line 71 in which the current flows mainly is about 505 nm. The write bit line 71 has a large distance from the free layer as compared with the word line 50 in this manner, but has a larger pitch, and therefore a possibility that disturbance is caused is low. Since the distance from the free layer is small in the word line 50, a possibility that the disturbance is caused is low, and the pitch can be reduced.

Moreover, even in the structure of the present embodiment, there are advantages that a material and structure in which the current is easily flown can be set to the write bit line 71, and a structure and material advantageous in forming the good-quality TMR 52 can be set to the read bit line 70 in a resistance range capable of reading the data.

It is to be noted that the present invention is not limited to the above-described embodiments, and especially numerical values described in the respective embodiments indicate concrete examples and are non-restrictive, and it is clear that the respective embodiments can be appropriately changed in the scope of a technical idea of the present invention.

### INDUSTRIAL APPLICABILITY

As described above, according to the present invention, a wiring more distant from a magnetoresistance element can be set to a bit line or a write bit line, and a wiring closer to the magneto-resistance element can be set to a word line. Accordingly, there can be provided a semiconductor storage device in which a pitch of the word line can be reduced, disturbance is suppressed, and a degree of integration is high.

1. A semiconductor storage device in which a wiring of a first system and a wiring of a second system nonparallel to each other are so arranged as to intersect, and a magneto-resistance element as a storage element is disposed in a portion corresponding to an intersecting portion between the wiring of the first system and the wiring of the second system, the magneto-resistance element comprising a free magnetic layer whose magnetization direction changes with a direction of a current flowing through the wiring of the first system of the intersecting portion,
wherein a distance from the free magnetic layer to the wiring of the first system is larger than that from the free magnetic layer to the wiring of the second system.

2. The semiconductor storage device according to claim 1, wherein the magneto-resistance element is disposed between the wiring of the first system and the wiring of the second system.

3. The semiconductor storage device according to claim 1, wherein the wiring of the second system is positioned between the magneto-resistance element and the wiring of the first system.

4. The semiconductor storage device according to claim 1, wherein a width of the wiring of the second system is smaller than that of the wiring of the first system.

5. The semiconductor storage device according to claim 1, wherein the free magnetic layer is positioned in the vicinity of one surface of the magneto-resistance element, and the wiring of the second system is disposed on a side facing the one surface of the magneto-resistance element.

6. The semiconductor storage device according to claim 1, wherein the free magnetic layer is positioned in the vicinity of one surface of the magneto-resistance element, and the wiring of the second system is disposed on a side facing a surface opposite to the one surface of the magneto-resistance element.

7. The semiconductor storage device according to claim 1, wherein the wiring of the first system and the wiring of the second system are arranged at predetermined repetition pitches, and the repetition pitch of the wiring of the first system is lager than that of the wiring of the second system.

8. The semiconductor storage device according to claim 1, wherein the magneto-resistance element has a shape longer in one axis direction.

9. The semiconductor storage device according to claim 8, wherein the magneto-resistance element has a shape longer in a direction of the wiring of the second system rather than a direction of the wiring of the first system.

10. The semiconductor storage device according to claim 1, wherein the wiring of the first system is a bit line, and the wiring of the second system is a word line.

11. The semiconductor storage device according to claim 1, wherein the wiring of the first system is a write bit line, the wiring of the second system is a word line, and a read bit line having the same direction as that of the wiring of the first system is disposed separately from the wiring of the first system and the wiring of the second system.

12. The semiconductor storage device according to claim 11, further comprising: a bit line control circuit which executes a control in such a manner as to supply a current for writing to both the write bit line and the read bit line.

13. The semiconductor storage device according to claim 11, wherein the read bit line is disposed on the same side as that of the write bit line with respect to the magneto-resistance element.

14. The semiconductor storage device according to claim 11, wherein the read bit line is disposed on a side opposite to that of the write bit line with respect to the magneto-resistance element.

15. The semiconductor storage device according to claim 1, wherein the magneto-resistance element is constituted of the free magnetic layer, a tunneling insulating layer, a pinned magnetic layer, and an antiferromagnetic layer stacked in this order.

16. The semiconductor storage device according to claim 1, wherein the wiring of the first system is constituted of a plurality of layers constituting the wiring of the first system, and the distance from the free magnetic layer to the wiring of the first system is a distance from the free layer to a layer in which a current flows mainly in the layers corresponding the wiring of the first system.

17. The semiconductor storage device according to claim 1, wherein the wiring of the second system is constituted of a plurality of layers constituting the wiring of the second system, and the distance from the free magnetic layer to the wiring of the second system is a distance from the free layer to a layer in which a current flows mainly in the layers corresponding the wiring of the second system.

18. The semiconductor storage device according to claim 1, wherein the magneto-resistance element is connected in series to a resistance element having nonlinear characteristics.
